(19) United States
(12) Patent Application Publication
(10) Pub. No.: US 2026/0231358 A1
(43) Pub. Date: Aug. 6, 2026

(54) COOLING SYSTEM AND APPARATUS

(71) Applicant: HEWLETT PACKARD ENTERPRISE DEVELOPMENT LP, Spring, TX (US)

(72) Inventors: Harvey John Lunsman, Chippewa Falls, WI (US); Robert Eugene Mascia, Chippewa Falls, WI (US); Robbie J. Rongstad, Osseo, WI (US)

(21) Appl. No.: 19/042,276

(22) Filed: Jan. 31, 2025

(51) Int. Cl. H05K 7/20; G06F 1/20

(52) U.S. Cl. CPC H05K 7/20254; G06F 1/206

(57) ABSTRACT

A system and cooling apparatuses. One cooling apparatus comprises an outer plate comprising a plurality of ramps, a spring plate comprising a plurality of spring fingers, wherein a higher density of spring fingers is located in an area of higher heat flux and a lower density of spring fingers are located in an area of lower heat flux and a cold plate comprising a coolant channel.

### INTRODUCTION

Computing devices generate heat as they operate. In the course of operation, those computing devices increasingly generate heat. Often those computing devices include pluggable modules that generate substantial heat. For example, some computing devices may include removable power supply units that require their own cooling.

Many of those computing devices may be higher capacity systems that utilize liquid cooling for heat management. For the liquid cooled computing devices, often the pluggable modules that generate substantial heat are also integrated within the liquid cooling system being utilized by the computing devices.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a block diagram illustrating an example of a cooling apparatus.

FIG. 2 is a block diagram illustrating an example system with an installed cooling apparatus.

FIG. 3 is a perspective view of an assembly of a cooling apparatus and a power supply cage.

FIG. 4 is a perspective view of the assembly of FIG. 3 with the power supply unit uninstalled.

FIG. 5 is a perspective view of the assembly of FIG. 3 with the power supply installed and unengaged.

FIG. 6 is a perspective view of the assembly of FIG. 3 with the power supply unit installed and engaged.

FIG. 7 is a perspective view of the outer plate and cold plate of the cooling apparatus of FIG. 3.

FIG. 8 is a perspective view of the outer plate and spring plate of FIG. 3.

FIG. 9A is a perspective view of the actuation mechanism of FIG. 3 in an unactuated state.

FIG. 9B is a perspective view of the actuation mechanism of FIG. 3 in an actuated state.

FIG. 10A is a perspective view of example ramps and spring fingers of FIG. 3 with the cooling apparatus in an unactuated state.

FIG. 10B is a perspective view of example ramps and spring fingers of FIG. 3 with the cooling apparatus in an actuated state.

FIG. 11 is a perspective view of an example wider profile spring finger.

FIG. 12 is a perspective view of an example narrower profile spring finger.

The drawings are included to provide a further understanding of the present disclosure and are incorporated in and constitute a part of this specification. The drawings illustrate one or more examples of the present teachings and together with the description explain certain principles and operations. In some occasions, details that are not necessary for an understanding of an instance of this disclosure or that render other details difficult to perceive may have been omitted.

### DETAILED DESCRIPTION

Pluggable modules that require heat management in liquid cooled systems, such as high-performance computing systems or other multi-node computing systems, require solutions for balancing the need for close contact with the liquid cooling system with the friction generated by the removability from, and insertion into, the system which is inherent in a module being pluggable. For example, utilizing a pluggable power supply unit (PSU) with a liquid cooling system requires the balancing of maintaining close contact between a cooling component of the cooling system, such as a cold plate, which is necessary for efficient heat exchange, and the friction that is generated on insertion of the PSU.

Many solutions exist for inserting the components using high-capacity lubricants. However, the use of the lubricants does not completely remove the friction on insertion and removal, which wears on the removable component over time. Another issue related to this solution is the need for constant reapplication of lubricants, as well as the mess such lubricants can create. This issue may be particularly acute in systems where the pluggable modules are constantly being removed and inserted.

One particular use of liquid cooling with pluggable modules that addresses many of the issues identified above is disclosed in U.S. application Ser. No. “18/362,358” filed on “Jul. 31, 2023” and titled “LEVER ACTUATED COLD PLATE”, which is incorporated herein by reference in its entirety.

The above-mentioned application provides a lever actuated cold plate that can be moved into and out of engagement with the pluggable component by the actuation of the lever. This overcomes the friction issues identified above because the cold plate can be moved out of engagement with the component during its insertion or removal, while still being able to provide close contact between the cold plate of the cooling system and the pluggable components because the cold plate can be moved back into engagement with the component after its insertion. To engage the cold plate with the pluggable component, a lever is actuated to move a spring plate against ramps, which moves the spring plate towards the cold plate and compresses spring fingers of the spring plate therebetween. This pushes the cold plate against the pluggable component, generating the pressure needed to ensure a good thermal interface.

However, while the above-described lever actuated cold plate mechanism can be effective, in some cases the amount of force needed to actuate the lever may be higher than is desired. Establishing a good thermal interface may require the application of high pressure between the cold plate and pluggable component, and such high pressures may require the use of strong spring fingers which are hard to compress, making the actuation of the lever difficult. Furthermore, in some cases, some parts of a module may receive less cooling than may be desired.

To address these and other issues, this disclosure provides example actuatable cold plate mechanisms for liquid cooling pluggable modules in which lower actuation forces and more efficient heat exchange can be achieved by providing concentrated pressure on hotter areas of the components. Often pluggable components, such as PSUs, have sections that generate more heat than other sections. Relatively high pressure by the cold plate may be needed to adequately cool these higher heat sections, but cooler sections of the pluggable component do not necessarily need as much pressure to remain adequately cooled. Accordingly, applying pressure evenly across the cold plate is wasteful, as more pressure than is necessary ends up being applied to the cooler sections in order to ensure that the hotter sections get sufficient pressure. On the other hand, in examples disclosed herein the pressure applied by the cold plate is concentrated in the hotter areas, which allows for less pressure to be applied to cooler areas, and therefore the total amount of pressure being applied across entire cold plate can be reduced. This translates into a reduction in the amount of that is needed to actuate the cold plate while still providing adequate cooling.

For example, some actuatable cold plate mechanisms of this disclosure may have spring plates in which the spring fingers thereof are positioned in an uneven distribution across the spring plate, with a higher concentration of spring fingers in regions aligned with hotter areas of the pluggable component and lower concentrations of spring fingers (including omission of spring fingers entirely, in some cases) in areas that generate less heat. This uneven positional distribution of spring fingers can allow for the overall number of spring fingers which are needed to be reduced, as fewer springs are provided in the cooler areas. Because the total number of spring fingers is reduced, less force may be needed to actuate the spring plate.

As another example, actuatable cold plate mechanisms of this disclosure may have spring plates in which multiple different sized spring fingers are used, with the sizes being varied across the plate so as to concentrate pressure in hotter areas. Specifically, larger spring fingers which generate higher pressure may be provided in hotter sections of the components, while smaller spring fingers which generate lesser pressure may be provide to sections requiring lower heat exchange. In sections that require minimum heat exchange, no spring fingers may be present.

In various examples, the uneven spring finger distribution (which may be a locational distribution, a size distribution, or a combination of the two) may be based on a heat flux map of the pluggable module being used with the system.

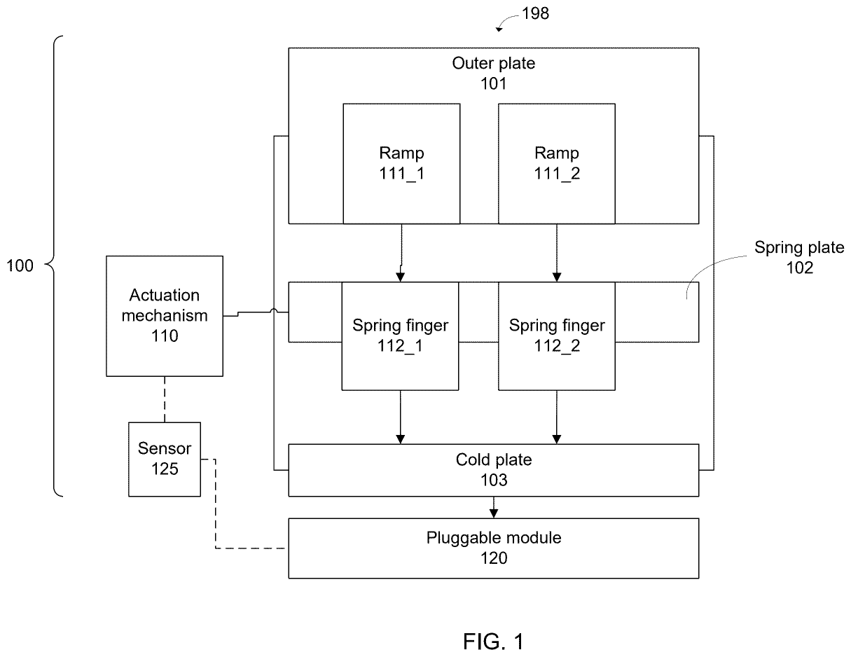

These and other examples will be described in greater detail below in relation to FIGS. 1-12.

Now referring to FIG. 1, a cooling assembly 198 is presented. Cooling assembly 198 includes a cooling apparatus 100 and a pluggable module 120. Cooling apparatus 100 is configured to be installed in an information processing system, such as a server, networking device, or other information processing system. Specifically, the cooling apparatus 100 is disposed in, or adjacent to, a bay of the information processing system which is to removably receive a pluggable module. Cooling apparatus 100 is also configured to be placed in removable thermal contact with a pluggable module 120 in an installed state of the pluggable module 120 in the bay of the information processing system. In particular, cooling apparatus 100 is also configured to provide targeted thermal contact with pluggable module 120.

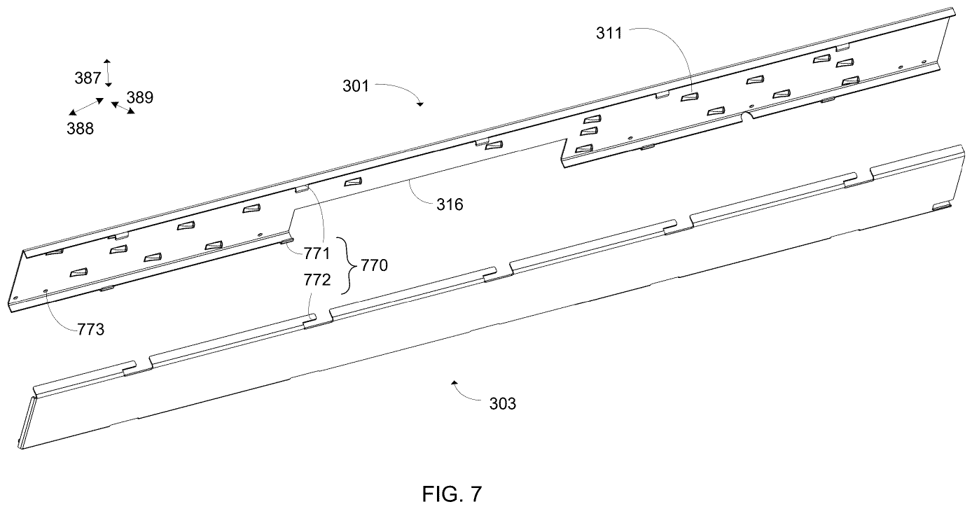

Cooling apparatus 100 includes an outer plate 101, a spring plate 102 and a cold plate 103. In instances, cooling apparatus 100 may include an apparatus housing. In some instances, the apparatus housing may include one or more brackets that provide structural support to the outer plate 101 and the cold plate 103. In some instances, the one or more brackets may be configured to engage with receptacles of the outer plate 101 and/or cold plate 103. For example, the one or more brackets may include attachment features throughout the length of the apparatus housing in locations configured to match the receptacles of the outer plate 101 and/or cold plate 103. In some examples, only the outer plate 101 may be attached to the apparatus housing, through attachment features of the one or more brackets, where the cold plate 103 is secured to the outer plate 101 through plate attachments. Example attachment features and plate attachments will be described in reference to FIG. 7.

In instances, cooling apparatus 100 may include one or more cooling components configured to be in direct thermal connection with the cold plate 103 and indirect thermal connection to the pluggable module 120 through the cold plate 103. In an example, the one or more cooling components may be a liquid cooling component, such as a copper pipe through which liquid coolant flows. In examples, the liquid cooling component may be hydraulically connected to a liquid cooling system of a computing apparatus. During operation, heat is absorbed from the cold plate 103 by the cooling components and then this heat is transferred into the liquid coolant flowing through the cooling components. The liquid coolant may then be cooled by external cooling systems (such as a heat exchanger).

The outer plate 101 comprises a plurality of ramps 111. As used herein, a “ramp” is a protrusion from a bottom face of the outer plate 101 with a sloped surface which is at an acute angle relative to the bottom face (the bottom face being the one which faces the spring plate 102). The ramps 111 may be formed as an emboss on the outer plate 101 that is indented toward the spring plate 102 in a ramp-like shape. In instances, the ramps 111 are distributed on the outer plate 101 based on the heat generation of the pluggable module 120. For example, ramps 111 may be distributed throughout the outer plate 101 as to match the areas of the pluggable module 120 that generate most heat.

The spring plate 102 includes a plurality of spring fingers 112. As used herein, a “spring finger” is a cantilevered spring with an attached end joined to a planar portion of the spring plate 102 and a free end that is movable relative to the planar portion of the spring plate 102. In a resting or default state of the spring finger 112, it protrudes at an acute angle downward from the planar portion of the spring plate 102 towards the cold plate 103. The free end is movable upward (away from the cold plate 103), which causes elastic deformation of the spring finger 112 and the generation of a restoring spring force urging the spring finger 112 downwards. The spring fingers 112 and the planar portion of the spring plate 102 can integrally connected together, with both being formed from the same sheet or plate (e.g., by cutting/bending/stamping the sheet or plate).

The spring fingers 112 are configured to engage with respectively corresponding ramps 111. In instances, the engagement between an ramp 111 and a respective spring finger 112 includes moving a section of the spring finger 112 based on the movement of the ramp 111. For example, one end of the spring finger 112 may move towards the cold plate 103 based on the interaction of the spring finger 112 with the ramp 111.

In some instances, spring fingers 112 are arranged in an uneven (i.e., non-uniform, irregular) positional distribution across the spring plate 102. In particular, the spring fingers 112 may be positionally arranged based on a heat map of the pluggable module 120, with greater concentrations of spring fingers 112 in regions aligned with hotter sections of the pluggable module 120 and lower concentrations of spring fingers 112 in regions aligned with cooler sections of the pluggable module 120. It should be noted that this uneven positional distribution of spring fingers 112 can allow for fewer total spring fingers to be included in the spring plate 102 while still providing adequate pressure to the areas that need it. Because fewer spring fingers 112 are included, the total force needed to actuate the actuation mechanism 110 can be smaller.

The amount of spring force that a spring finger 112 generates when compressed, i.e., load capacity of the spring finger 112 can be tuned to a desired value by changing the dimensions of the spring finger 112, such as the width of the spring finger. For example, in a shorter width, spring finger 112 may apply 2.5 pounds of force to the cold plate 103. In an example, in a wider width, spring finger 112 may apply 5 pounds of force to the cold plate 103 when compressed the same amount. In some instances, spring plate 102 may include spring fingers 112 all of same width. In other instances, spring plate 102 may include spring fingers 112 of multiple widths. For example, based on the heat distribution of the pluggable module 120, spring plate 102 may include spring fingers 112 of higher load capacity to apply higher force to areas of the pluggable module 120 that generates more heat and spring fingers 112 of lower load capacity to apply lower force to areas of the pluggable module 120 that generate less heat. It should be noted that this distribution of multiple load capacity spring fingers 112 enables the total force applied as a function of an interaction with the actuation mechanism 110 to be more efficiently applied, with a stronger contact with the areas of higher temperature of the pluggable module 120. For example, the widths of the spring fingers 112 may be varied based on the position of the spring finger 112 and the heat distribution of the pluggable module 120, such that spring fingers 112 in regions aligned with hotter sections of the pluggable module 120 are provided with greater widths than spring fingers 112 provided in regions aligned with cooler sections of the pluggable module 120. A person with ordinary skill in the art will appreciate that a higher the load being applied by a spring finger 112 causes a higher contact pressure between the pluggable module 120 and the cold plate 103 at the section where the force is being applied, thus translating to a higher thermal energy transfer between the cold plate 103 and the pluggable module 120 at that section. The cold plate 103 is configured to be in thermal contact with a pluggable module 120. In instances, the outer plate 101 and the cold plate 103 are configured to form a housing for one or more cooling tubes. The cooling tubes are configured to hydraulically connect with a cooling system of a computing system or device. In instances, the cooling tubes are in direct contact with the cold plate 103. In instances, the cold plate 103 is used as a medium for transferring thermal energy from the colling tubes to the pluggable module 120. In instances, the pressure from the spring fingers 112 on the cold plate 103, based on the movement of the spring fingers 112 towards ramps 111, translates to the thermal contact between the cold plate 103 with the pluggable module 120. For example, the thermal transfer between the cooling tubes and the cold plate 103 is higher at each point of contact between a spring finger 112 and the cold plate 103.

Cooling apparatus 100 further includes an actuation mechanism 110. In instances, engagement of actuation mechanism 110 causes movement of the spring plate 102 in a manner that compresses the spring fingers 112 against the cold plate 103, thus pushing the cold plate against the pluggable module 120. More specifically, actuation mechanism 110 is configured to, when actuated, apply a force to the spring plate 102 which urges it to move in a first direction parallel to the spring plate 102. As the spring plate 102 moves in the first direction, the attached ends of the spring fingers 112 slide along and ride up the sloped surfaces of the ramps 111, which forces the spring plate 102 to also move towards the cold plate 103 along a second direction perpendicular to the first direction. In other words, when the actuation mechanism 110 is actuated, the spring plate 102 moves simultaneously in both the first direction and the second direction, i.e., the spring plate 102 moves at an angle relative to the outer plate which corresponds to the slope of the ramp. This motion of the spring plate 102 towards the cold plate 103 results in the free ends of the spring fingers 112 being pressed against the cold plate 103, and if the cold plate 103 is prevented from moving, for example because it is in contact with a pluggable module, then the motion of the spring plate 102 towards the cold plate 103 causes the spring fingers 112 to be compressed by the cold plate 103. In this compressed state, the spring fingers 112 generate a spring force which presses the cold plate 103 against the pluggable module 120.

Conversely, if the actuation mechanism is actuated in the opposite direction, the reverse of the process described above occurs, resulting in the spring plate 102 being retracted and the spring fingers 112 being decompressed. This can allow for easier insertion or removal of the pluggable module 120

As noted above, each spring finger 112 may have the same or different load capacities, and the distribution of the spring fingers 112 are based on the heat generation of the pluggable module 120. For example, the distribution of the spring fingers 112 may be based on a heat map of the pluggable module.

In some instances, cooling apparatus 100 may include a sensor 125. Sensor 125 may include any sensor used for detecting the actuation of the actuation mechanism 110. For example, actuation mechanism 110 may be a lever where sensor 125 may be a proximity sensor configured to detect when the lever is engaged. In instances, the connection between a computing system and the pluggable module 120 is only established when sensor 125 detects actuation of the actuation mechanism 110. For example, pluggable module 120 may be attached to a computing system, such as through a PSU connector, but no data or electrical signals are transferred until sensor 125 detects actuation of the actuation mechanism 110. In instances, the use of sensor 125 may prevent pluggable module 120 from beginning operation without the proper cooling provided through the optimal thermal contact with the cold plate 103.

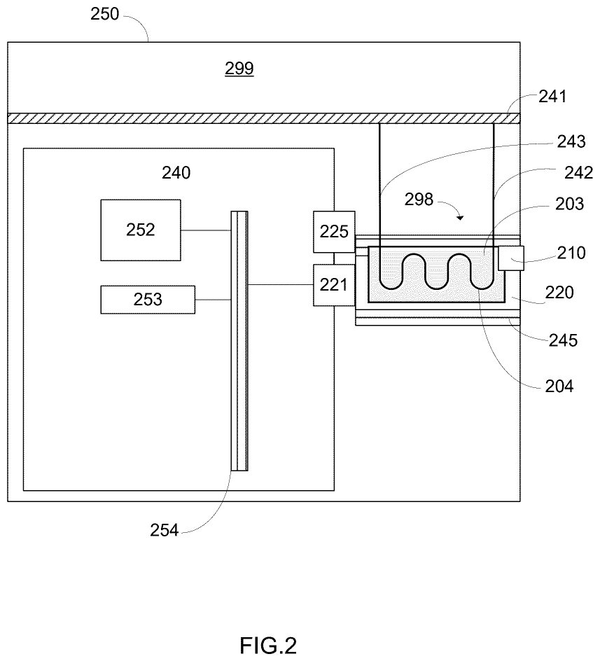

Now referring to FIG. 2, an example system 299 is shown. System 299 is an information processing system, such as a hypercomputing device, or other information processing system. System 299 includes a chassis 250, a primary system board 240 supported by the chassis 250, a cooling system 241, a pluggable module 220 removably installable in system 299, and a cooling apparatus 200 hydraulically connected to the cooling system 241 and in thermal contact with pluggable module 220. Primary system board 240 includes a power connector 221 configured to connect to a connector of the pluggable module 220. Cooling apparatus 200 includes all components of colling apparatus 100 and additionally includes a cooling system connector 242 and a cooling component 204. Cooling apparatus 200 also includes cooling housing 245. Components of FIG. 2 that share the same last two digits as components of FIG. 1 may be the same, or include, the component of FIG. 1. For example, pluggable module 220 may be the same as pluggable module 120. System 299 also includes at least a processor 252 and at least a memory 253 communicatively connected to the primary system board 240.

A “chassis,” as used herein, is a support structure, such as an enclosure or tray, designed to support, and in some cases house, hardware components, such as primary system board 240. In instances, chassis 250 may house primary system board 240. In instances, primary system board 240 may be attached to a section of chassis 250. A “system board,” as used in this disclosure, is a central circuit board comprising a central processing unit (CPU) and supporting circuitry, and configured to enable connection and integration among a plurality of components and devices. As noted above, processor 252 is communicatively connected to primary system board 251. As used herein, a “processor” is a component configured for executing instructions, performing calculations and managing tasks. In instances, system 299 may include two or more processors 252 mounted to primary system board 251. In an example, without limitations, processor 252 may be a Central Processing Unit, (CPU).

As also noted above, memory 253 is communicatively connected to primary system board 240. As used in this disclosure, a “memory” is a data storage component configured to store instructions for a computing component, such as processor 652. In examples, without limitations, memory 653 may be configured for temporary storage of data, such as a random-access memory (RAM), or permanent data storage, such as Solid-State drives (SSD).

Primary system board 240 includes conductive pathways 254. As used herein, conductive pathways 254 are pathways in the primary system board 240 used for electrical and data transfers. Power connector 221 is communicatively connected to conductive pathways 254. Pluggable module 220 may be electrically, and communicatively, connected to components of primary system board 240 via the conductive pathways 254. In instances, processor 252 and/or memory 253 may communicate with each other via the conductive pathways 254. Pluggable module 220 may connect to primary system board 240. In instances, the conductive pathways may be a bus. A “bus,” as used herein, is a component configured for transmitting data. The bus may include multiple types of bus structures, and combinations thereof, such as memory bus, memory controller, peripheral bus, local bus, and the like.

Cooling system connector 242 is hydraulically connected to the cooling system 241. In instances, cooling system connector 242 is a liquid cooling conduit for exchanging liquid coolant between the cooling system 241 and the cooling apparatus 200. In instances, cooling system connector 242 may include a coolant inlet for bringing coolant fluid to the cooling apparatus 200 and a coolant outlet for removing coolant fluid from the cooling apparatus 200. As noted above, cooling apparatus 200 includes a cooling component 204. Cooling component 204 is in thermal contact with cold plate 203 of the cooling apparatus 200. As described in reference to FIG. 1, cold plate 203 is in thermal contact with pluggable module 220, in an actuated state, thus cooling component 204 is thermally connected to the pluggable module 220 via cold plate 203. As used throughout this disclosure, an “actuated state” of the cooling apparatus 200 refers to the cold plate 203 being in contact with the pluggable module 220 based on the actuation of the actuation mechanism. As described in reference to FIG. 1, cold plate 203 becomes in thermal contact with the pluggable module 220 based on an actuation of actuation mechanism 210.

In instances, cooling component 204 may be a coolant conduit, such as a pipe, that is hydraulically connected to the cooling system 241 through the cooling system connector 242.

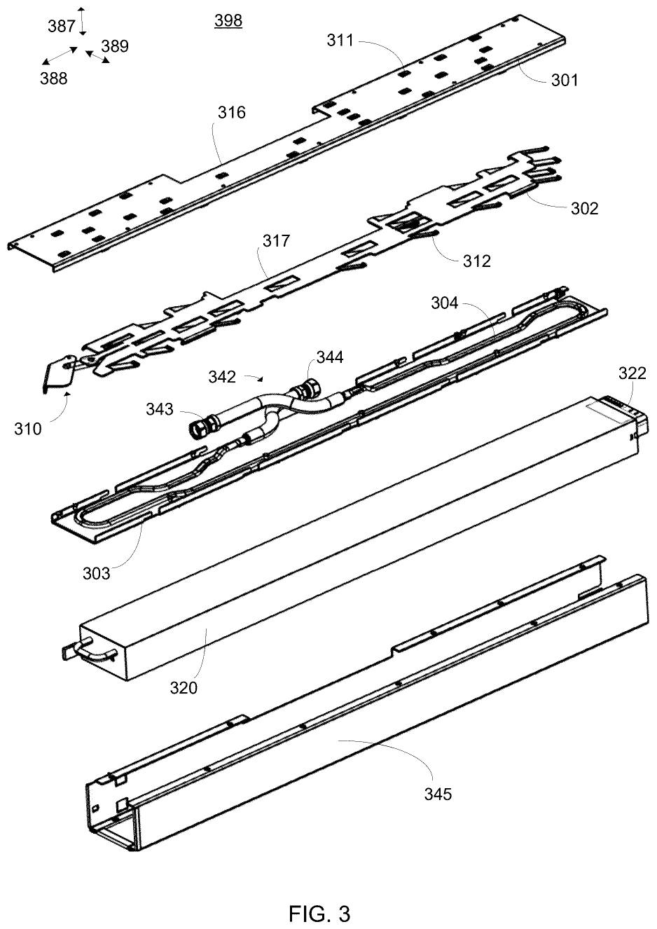

In instances, cooling housing 245 is attached to chassis 250. Cooling housing 245 may include brackets configured to secure outer plate, not shown for illustrative purposes, and cold plate 203. The brackets are also configured to secure removable module 220 in thermal connection with cold plate 203. In some instances, cooling housing 245 may include attachment features used for securing cooling housing 245 to the chassis 250. In instances, the attachment features of the cooling housing 245 may attach to outer plate. In examples the attachment features may be threaded holes for fasteners, that are used for attaching the cooling housing 245 to the chassis 250. In some instances, attachment features may provide attachment to both the outer plate and the chassis 250. For example, the outer plate may include fastening holes aligned with respective attachment features of the cooling housing 245. In instances, the attachment features and fastening holes of the outer plate may be aligned with attachment holes of the chassis 250. For example, the outer plate and cooling housing 245 may both be attached to chassis 250 via the attachment features. Example brackets and attachment features of the cooling housing are described in reference to FIGS. 3-6 further below.

As described in reference to FIG. 1, cooling assembly 298 includes an actuation mechanism 210. In some instances, cooling assembly 298 may include a sensor 225. Sensor 225 may be communicatively connected to a power connector of the removable module 220. For example, sensor 225 may prevent communication, including power transfer, between the removable module 220 and the power connector 221 of the primary system board 240.

Now referring to FIG. 3-12, an example Cooling assembly 398 will be described. Cooling assembly 398 is an example implementation of colling assembly 198/298. Cooling assembly 398 includes a cooling apparatus 300 and a power supply unit (PSU) 320. The terms PSU 320 and pluggable module 320 will be used interchangeably to describe the examples. It should be noted that although a PSU is described in this example, other types of pluggable modules may be included. Cooling apparatus 300 is an example implementation of cooling apparatus 100, while PSU 320 is an example implementation of pluggable module 120/220. The components of Cooling assembly 398 are described simultaneously below for ease of understanding. However, it should be noted that cooling apparatus 300 and PSU 320 may be produced or sold together or separately and may be claimed separately or together herein. Elements in FIGS. 3-12 and elements of FIGS. 1-2 whose reference numbers have the same last two digits as elements described above in relation to FIGS. 1 and 2, such as 102 and 302, correspond to one another, with elements in FIGS. 3-12 being one implementation example of the corresponding element in FIG. 1-2.

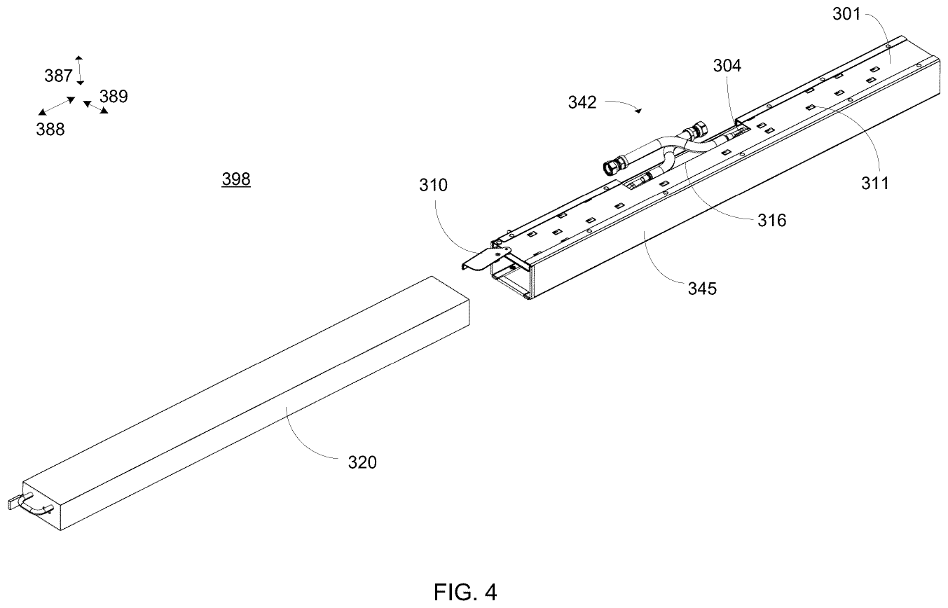

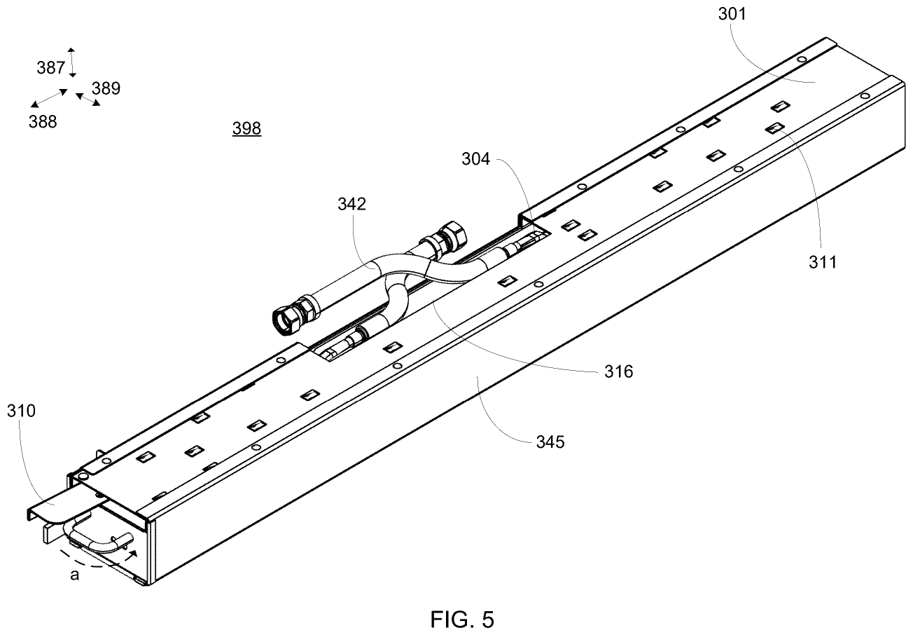

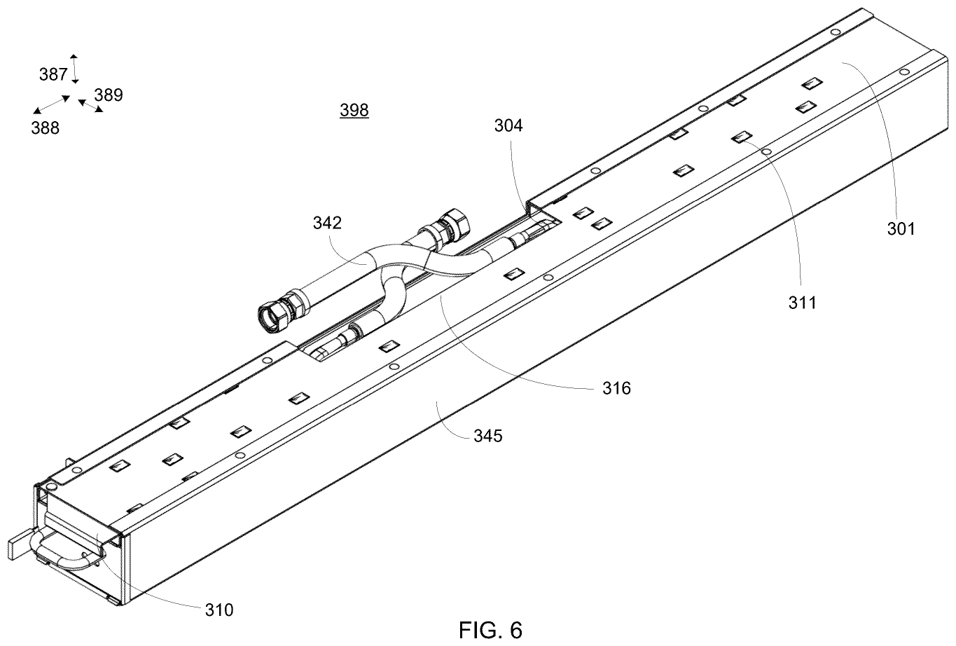

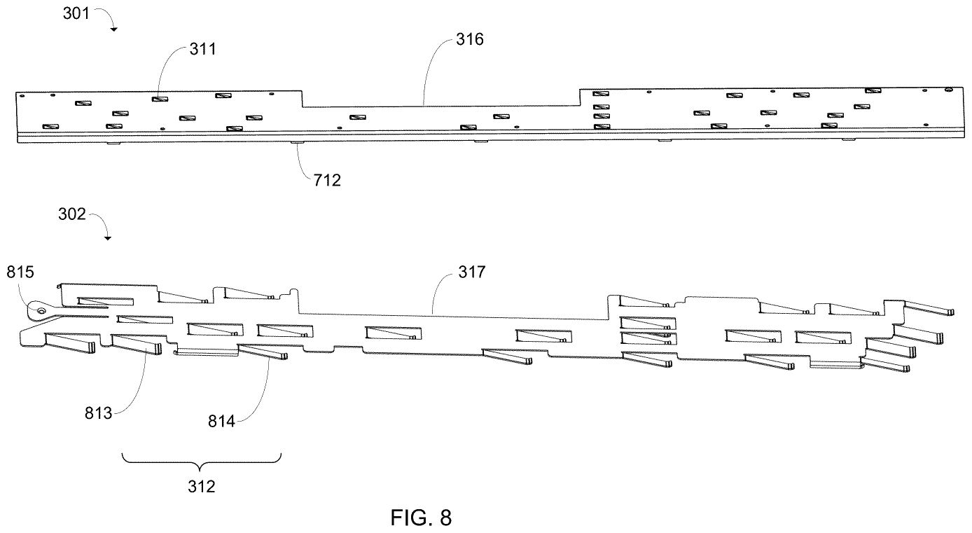

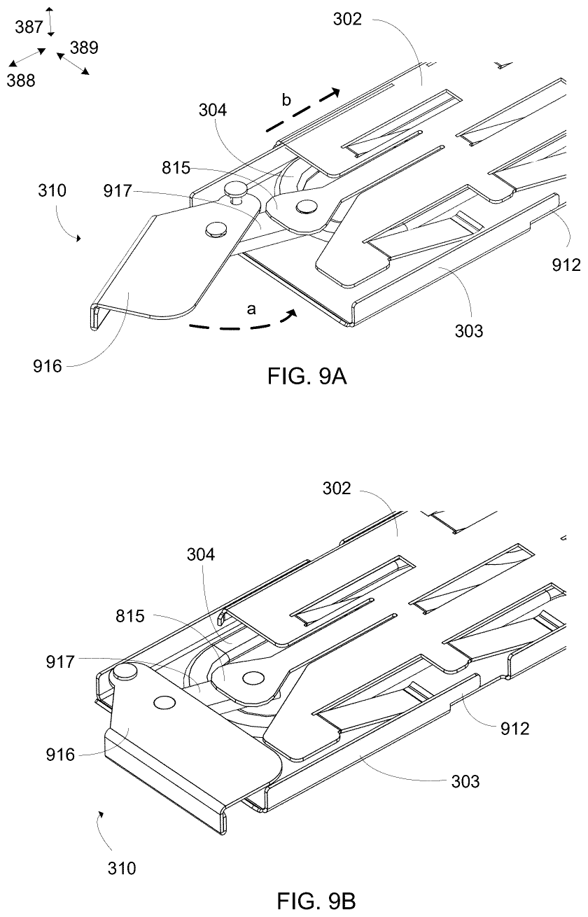

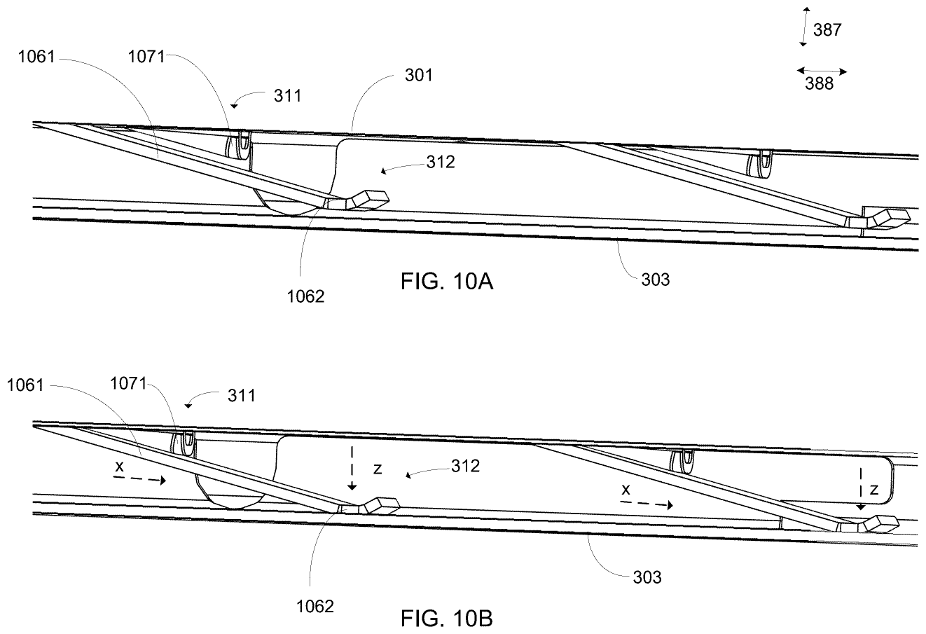

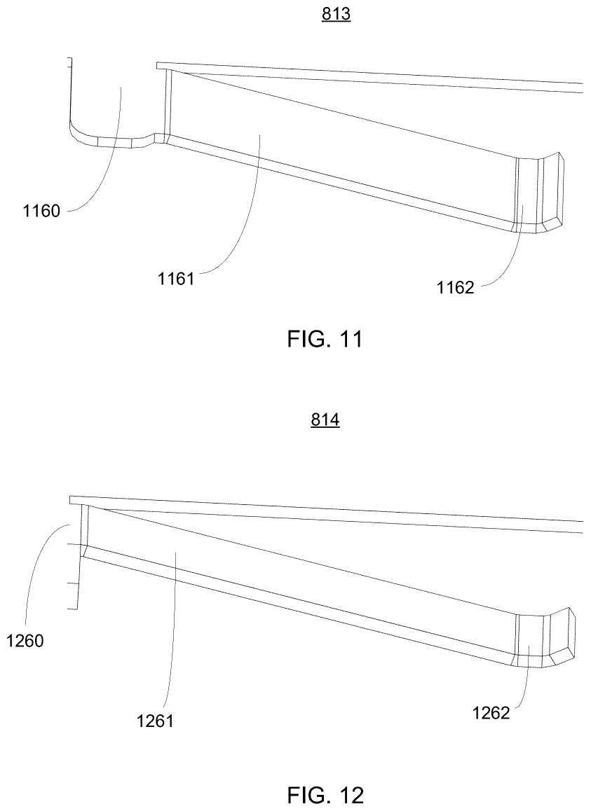

FIG. 3 shows the example cooling assembly 398. FIG. 4 shows the cooling assembly 398 with PSU 320 uninstalled and actuation mechanism 310 unactuated. FIG. 5 shows cooling assembly 398 with PSU 320 installed and actuation mechanism 310 unactuated. FIG. 6 shows cooling assembly 398 with PSU 320 installed and actuation mechanism 310 actuated. FIG. 7 shows the side of outer plate 301 facing the cold plate 303. FIG. 8 shows the outer plate 301 and spring 302 with each ramp 311 align with a respective spring feature 312. FIG. 9A shows the actuation mechanism 310 in an unactuated state, while FIG. 9B shows actuation mechanism 310 in an actuated state. FIG. 10A shows outer plate 301 and spring plate 302 in a disengaged state, while FIG. 10B shows outer plate 301 and spring plate 302 in an engaged state. FIG. 11 shows a higher load spring finger 813 and FIG. 12 shows a lower load spring finger 814.

Elements in FIG. 3-7 and elements of FIGS. 1-2 whose reference numbers have the same last two digits as elements described above in relation to FIGS. 1 and 2, such as 102 and 302, correspond to one another, with elements in FIGS. 3-12 being one implementation example of the corresponding elements in FIGS. 1-2.

Elements in reference to FIGS. 3-10 are described using vertical 387, longitudinal 388 and latitudinal 389 directions for ease of description. Vertical direction 387 is perpendicular to a face of the cooling apparatus 300. Longitudinal 388 and latitudinal 389 directions are perpendicular to each other and to the vertical direction 387 and may both also be referred to as being a “horizontal” direction on occasion. However, it should be noted that these directional descriptions are used only relative to the position of the cooling housing 345. As such, for example, vertical position 387 could include a horizontal position relative to the ground, depending on the orientation of the colling housing 345. Motions related to the actuation of actuation mechanism 310 in reference to FIGS. 9A-9B and to movement spring plate 302 relative to outer plate 301 in reference to FIGS. 10A-10B are described using alphabetical letters. For example, one motion is described with the letters “a”, while another motion is described with a letter “b”, and so forth. The order that the motions are described, or letters used, should not be interpreted as limiting the motions to the order described, unless explicitly stated otherwise.

Referring to FIG. 3, the pluggable module 320 includes a board connector 322. In instances, the board connector 322 may include a sensor configured to detect actuation of actuation mechanism 310. In instances, the sensor may be communicatively connected to a controller configured to enable and disable connection between the pluggable module 320 and an information system which it is being installed.

The example cooling assembly 398 also includes actuation mechanism 310. Actuation mechanism 310 is an example implementation of actuation mechanism 110/210 described in reference to FIGS. 1 and 2. In instances, actuation mechanism 310 may be a lever.

As noted above, the example cooling assembly 398 includes a coolant conduit 304 and a cooling system connector 342. Coolant conduit 304 and cooling system connector 342 are example implementations of cooling component 204 and cooling system connector 242, respectively. Cooling system connector 342 includes an inlet connector 343 and an outlet connector 344. The inlet connector 343 and outlet connector 344 may be made of flexible material such as polymer and the like. In this example, the coolant conduit 304 receives coolant from a cooling system, not shown, via inlet connector 343. In this example, coolant conduit 304 has a serpentine shape that curves back and forth throughout the length of the cold plate 303. The coolant conduit 304 may be made of thermally conductive materials such as aluminum, copper, or the like. In instances, coolant conduit 304 is shaped in a manner as to maximize contact with higher heat areas of the cold plate 303. For example, coolant conduit 304 may be shaped to maximize surface contact with cold plate 303 in area where the pluggable module 320 generates higher amount of heat. In examples, coolant conduit 304 may be placed on cold plate, such as with flexible piping coolant conduit 304, or designed, such as with rigid pipping, such as copper pipes, based on a heat map of the pluggable module 320. Once coolant has traversed the length of the coolant conduit 304, coolant conduit 304 directs the coolant, such as hot coolant from the cold plate 303, to the outlet connector 344.

Outer plate 301 and spring plate 302 include connector clearance 316 and 317, respectively, which are cutout areas of the plate to enable placement of the cooling system connector 342.

The example cooling assembly 398 also includes an outer plate 301 that includes a plurality of ramps 311. Cooling assembly 398 includes spring plate 302 which includes a plurality of spring fingers 312. As discussed in reference to FIG. 1, each ramp 311 is aligned with a respective spring finger 312. As discussed throughout this disclosure, the layout, or distribution, of the aligned spring fingers 312 and ramps are based on the heat distribution of the pluggable module 320 being used. For example, outer plate 301 and spring plate 302 may have a layout of respective ramps 311 and spring fingers 312 based on a heat map of the PSU 320. As discussed above, the placement of the coolant conduit 304 is also based on the heat distribution of the pluggable module 320. In instances, the coolant conduit 304 may be a pipe that weaves around the spring fingers 312. Likely as close as possible without making contact with the spring finger 312 as to maximizer the heat exchange with the pluggable module 320.

As discussed in reference to FIG. 1, spring plate 302 may include multiple sizes of spring fingers 312. For example, a spring finger with a higher width may provide higher load, thus enabling stronger heat exchange for sections with higher heat generation, while a spring finger with lower width may provide a lower load, which may enable lower heat exchange for areas with lower heat generation. As noted above, the distribution of spring fingers 312 is used for maximizing heat exchange, thus areas with comparatively low heat generation may include no spring fingers. Referring to FIGS. 8, 11 and 12, two example sizes, wide finger 813 and narrow finger 814, of spring fingers 312 are presented. As noted throughout this disclosure, other sizes may be included, with wider sizes being used to provide higher loads. It should be noted that the total load provided through the actuation mechanism 310 is the same regardless of the distribution of spring fingers 312, thus the total load applied by the spring fingers 312 is limited to the total pressure available through actuation. As such, in instances, the use of wider sized spring fingers 312 may be limited to the hotter sections of pluggable module 320 to maximize heat exchange.

Referring to FIG. 7, the ramps 311 may be uniformly shaped to match the narrowest spring finger 312. This configuration enables rearrangement of loads provided by the spring fingers 312 only by changing the sizes of the spring fingers 312. In instances, each ramp 311 may be shaped with a width to match the width of its respective spring finger 312. Although this configuration may require changing the sizes of both ramps 311 and spring fingers 312, it may enable higher efficiency in deforming a spring finger 312 due to the higher contact surface are between the components. It should be noted that in either configuration, the new plates would need to be made if the distribution of the heat generation is changed. For example, in a situation where a different type of PSU 320 is used.

As shown in FIGS. 10A and 10B, spring fingers 312 include a contact section 1061 which is configured to deform based on contact with angled protrusion 1071 of ramp 311. Angled protrusion 1071 is angled in a ramp shape as to guide the contact section 1061 to deform vertically 387 toward the cold plate 303, causing contact between the fingertip 1062 and the cold plate 303, shown by direction label “z” in FIG. 10B. The spring finger 312 deforms based on the movement labeled “x” in FIG. 10B, which shows the direction which the spring plate 302 moves based on action of actuation mechanism 310. The spring plate 302 includes an actuation coupler 815 configured to attach to actuation mechanism 310.

As shown in FIGS. 9A-9B, actuation mechanism 310 includes a lever 916 and an actuation linkage 917. Actuation linkage 917 is a bar with one side attaching to lever 916 and the other side attaching to the actuation coupler 815. FIG. 9A shows actuation mechanism 310 in an unactuated state. The label 916 is moved in the direction “a”, which causes actuation linkage 917 to push against actuation coupler, thus causing spring plate 302 to move longitudinally 388 in direction “b”. FIG. 9B shows actuation mechanism 310 in an actuated state. As described above in reference to FIG. 10A-10B, the movement I direction “b” causes spring fingers 312 to push against respective ramps 311, translating the force applied by the lever to distributed forces through the spring fingers 312.

The cold plate 303 and the outer plate 301 are static relative to the spring plate 302. As shown in FIG. 7, cold plate 303 and outer plate 301 are attached to each other through attachment features 770. Attachment features 770 comprise an outer plate attachment 771 and a cold plate attachment 772. In this example, outer plate attachment 771 is an angled notch that is inserted through an opening in cold plate attachment 772 and then slid towards a closed off section as to maintain the cold plate 303 secured to the outer plate 301. As described in reference to FIG. 2, the outer plate 301 is attached to the cooling housing 345. It should be noted that the brackets of cooling housing 345 secure the outer plate 301 in plate while the actuation mechanism 310 prevents the cold plate from disengaging from the outer plate 301. In instances, the outer plate 301 includes outer attachments 773. Outer attachments 773 may be holes for inserting a fastener. As discussed in reference to FIG. 2, outer plate 301 attaches to the cooling housing 345. In this example, outer attachments 773 are used for attaching to the cooling housing. In some instances, outer attachments 773 may be used for attaching outer plate 301 to the cooling housing and to a system board, not shown.

Referring to FIGS. 4-6, a method for installing pluggable module 320, which includes inserting the pluggable module 320 and actuating the actuation mechanism will be shown. As shown in FIG. 4, pluggable module 320 is inserted through the opening of the cooling housing which contains the actuation mechanism. The pluggable module 320 is inserted while actuation mechanism 310 is disengaged. Once inserted, as shown in FIG. 5, the actuation mechanism is actuated in direction “a”. See references to FIG. 9A-9B above for more detail. As shown in FIG. 6, once actuated, pluggable module 310 is locked within cooling housing and in an installed state both by the actuation mechanism 310 and the force applied by spring plate 302 based on its interaction with outer plate 310.

Referring to FIG. 11, an example of a wider finger 813 is presented. In this example, the wider finger 813 includes a plate connector 1160, a contact section 1161 and a fingertip 1162. As described above, the wider area of the fingertip 1162 provides higher load pressure to the cold plate 303, thus applying higher pressure to that section of the pluggable module 320, thus enabling higher heat transfer. Now referring to FIG. 12, a narrow finger 814 is shown, which also include a plate connector 1260, a contact section 1261 and a fingertip 1262, where the narrower tip translates to a lower load applied to the cold plate 303.

This disclosure provides a customized distribution of ramps 311 and spring fingers 312 that maximizes heat exchange by targeting sections of pluggable module 320 that generate more heat with higher loads. As such, it should be noted that multiple components of cooling assembly 398 include or are the same as components of U.S. application Ser. No. “18/362,358”, cited above, such as the cooling housing 345, the pluggable module 320 and the actuation mechanism 310. Accordingly, the descriptions in the above cited application are also applicable to the components described herein.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A cooling apparatus for cooling a pluggable module of an information processing device, comprising:
an outer plate comprising a plurality of ramps;
a spring plate comprising a plurality of spring fingers arranged in an non-uniform spatial distribution having a higher spring finger density in an area of higher heat flux and a lower spring finger density in an area of lower heat flux; and
a cold plate comprising a coolant channel, wherein the cold plate is configured to thermally connect to a pluggable module at a first side of the cold plate,
wherein the spring plate is movable along a first direction and, in response, an attached end of each spring finger slides along a corresponding ramp of the plurality of ramps which forces the spring plate to move in a second direction towards the cold plate causing the plurality of spring fingers to be compressed and press against a second side of the cold plate, generating contact pressure between the cold plate and the pluggable module.

2. The cooling apparatus of claim 1, wherein the plurality of spring fingers are equally sized to each other.

3. The cooling apparatus of claim 2, wherein each spring finger applies the same force to the cold plate.

4. The cooling apparatus of claim 1, wherein a subset of the plurality of spring fingers has larger dimensions than the remaining spring fingers.

5. The cooling apparatus of claim 4, wherein each of a larger dimension spring fingers provide higher force to the cold plate than each of the remaining spring fingers.

6. The cooling apparatus of claim 4, wherein a subset of ramps of the plurality of ramps has a larger dimension than the remaining ramps and wherein each of a larger dimension spring fingers slides along a corresponding larger dimension ramp of the subset of ramps.

7. The cooling apparatus of claim 1, wherein the coolant channel is arranged in a pattern based on the heat flux map.

8. The cooling apparatus of claim 1, wherein the cooling apparatus comprises a plate actuation mechanism which is actuatable to move the spring plate along the first axis parallel to the first direction.

9. The cooling apparatus of claim 8, wherein the plate actuation mechanism comprises a lever.

10. The cooling apparatus of claim 1, wherein the plurality of spring fingers applies 40 lbf of force to the pluggable module.

11. The cooling apparatus of claim 1, wherein the plurality of spring fingers applies 60 lbf of force to the pluggable module.

12. The cooling apparatus of claim 1, wherein each ramp of the plurality of ramps comprises a ramp emboss.

13. A computing system, comprising:
a chassis comprising a base and a power supply unit (PSU) bay;
a system board supported by the base;
a liquid cooling subsystem configured to cool the system board;
a power supply unit (PSU) removably installed in the PSU bay; and
a cooling apparatus to cool the PSU,, the cooling apparatus comprising:
an outer plate fixed relative to the PSU bay and comprising a plurality of ramps;
a spring plate comprising a plurality of spring fingers arranged in a pattern based on a heat flux map of the PSU; and
a cold plate comprising a coolant channel hydraulically connected to the liquid cooling system, wherein the cold plate protrudes into the PSU bay and is thermally connected to the PSU at a first side of the cold plate,
wherein the spring plate is movable along a first direction and, in response, an attached end of each spring finger slides along a corresponding ramp of the plurality of ramps which forces the spring plate to move in a second direction towards the cold plate causing the plurality of spring fingers to be compressed and press against a second side of the cold plate, generating contact pressure between the cold plate and the PSU.

14. The system of claim 13, wherein the system further comprises a plate actuation mechanism, wherein the pressure is applied to the plurality of spring fingers based on an actuation of the plate actuation mechanism.

15. The system of claim 14, wherein the PSU is electrically connected to the system board based on the actuation of the plate actuation mechanism.

16. The system of claim 14, wherein the plate actuation mechanism is a lever.

17. The system of claim 14, wherein the system further comprises a sensor configured to detect actuation of the actuation mechanism.

18. The system of claim 13, wherein a subset of the plurality of spring fingers has larger dimensions than the remaining spring fingers.

19. A cooling apparatus, comprising:
an outer plate comprising a plurality of ramps;
a spring plate comprising a plurality of spring fingers arranged in a pattern based on a heat flux map of a pluggable module; and
a cold plate comprising a coolant channel, wherein the cold plate is configured to thermally connect to the pluggable module at a first side,
wherein the spring plate is movable along a first direction and, in response, an attached end of each spring finger slides along a corresponding ramp of the plurality of ramps which forces the spring plate to move in a second direction towards the cold plate causing the plurality of spring fingers to be compressed and press against a second side of the cold plate, generating contact pressure between the cold plate and the pluggable module.

20. The cooling apparatus of claim 19, wherein a subset of the plurality of spring fingers has larger dimensions than the remaining spring fingers.
